(19) United States
(12) Patent Application Publication
(10) Pub. No.: US 2026/0072075 A1
(43) Pub. Date: Mar. 12, 2026

(54) TEST HANDLER FOR ELECTRONIC COMPONENT

(71) Applicant: MIRAE Corporation, Cheonan-si (KR)

(72) Inventors: KYUNG TAE KIM, Cheonan-si (KR); SUNG YONG YU, Cheonan-si (KR); UNG HYUN YOO, Cheonan-si (KR); SUN HWAL KIM, Cheonan-si (KR); KUK HYUNG LEE, Cheonan-si (KR)

(21) Appl. No.: 19/086,155

(22) Filed: Mar. 21, 2025

(30) Foreign Application Priority Data
Sep. 12, 2024 (KR) 10-2024-0125232

(51) Int. Cl. G01R 31/28

(52) U.S. Cl. CPC G01R 31/2867; G01R 31/2875; G01R 31/2877

(57) ABSTRACT

Disclosed relates to a test handler for an electronic component and a handling method of an electronic component. The test handler includes a loading unit performing a loading process of loading an electronic component on a tray and a test unit performing a test process of testing the electronic component stored in the tray. The loading unit loads the electronic component to be tested on the tray in an expansion state in which a size of each of storage grooves of the tray expands greater than a size of the electronic component, and contracts the tray to which the loading process is performed and switches the tray into a contraction state in which a size of each of the storage grooves is reduced.

### CROSS REFERENCE TO RELATED APPLICATION

The present application claims priority to Korean Patent Application No. 10-2024-0125232, filed Sep. 12, 2024, the entire contents of which are incorporated herein for all purposes by this reference.

### BACKGROUND OF THE INVENTION

### Field of the Invention

The present disclosure relates to a test handler for an electronic component to test an electronic component and handle the electronic component.

### Description of the Related Art

A memory semiconductor device, a non-memory semiconductor device, a central processing unit (CPU), etc., (hereinbelow, which will be referred to as the “electronic component”) are manufactured through some processes. For example, the electronic component may pass through some processes, such as a test process using a handler apparatus, such as a test handler, etc.

The test handler may perform a loading process, a test process, and an unloading process with respect to the electronic component. The loading process is a process of loading the electronic component from a user tray to a test tray. The test process is a process of connecting the electronic component stored in the test tray to a test apparatus. The test apparatus may perform a predetermined test with respect to the electronic component. The unloading process is a process of unloading the electronic component from the test tray to the user tray. In this case, the test handler may grade the electronic component according to a test result.

The loading process and the unloading process may be performed by a picker unit included in the test handler. The picker unit may pick up a plurality of electronic components from the user tray at the same time and store the electronic components in the test tray, performing the loading process. The picker unit may pick up the plurality of electronic components from the test tray at the same time and store the electronic components in the user tray, performing the unloading process. In this case, the test tray may include a plurality of storage grooves into which the plurality of electronic components is stored. Each of the storage grooves may have a size that is almost equal to the size of each electronic component. Accordingly, when the electronic components are stored in the storage grooves, the electronic components may be aligned to correspond to intervals and arrangement of the storage grooves.

In recent years, the need for miniaturization of electronic components has led to the development of electronic components called microchips. For example, electronic components such as high bandwidth memory (HBM), double data rate (DDR), graphics double data rate (GDDR), low power double data rate (LPDDR), etc. are actively developed.

As described above, as the electronic components are formed in a microscopic scale, the storage grooves should also be formed in a so as to have a size roughly matching the size of the electronic components. However, due to the limitation of controlling the picker unit, there is a problem of difficulty in storing an electronic component corresponding to a microchip in a storage groove having a microscopic scale.

### SUMMARY OF THE INVENTION

The present disclosure has been made keeping in mind the above problems occurring in the related art, and the present disclosure is intended to propose a test handler for an electronic component, the test handler being capable of improving the easiness and safety of a loading process with respect to an electronic component having a microscopic scale.

To solve the above-described objectives, the present disclosure has the following configuration.

According to the present disclosure, a test handler for an electronic component may include: a loading unit performing a loading process of loading an electronic component to be tested to a tray; and a test unit performing a test process of testing the electronic component stored in the tray. The loading unit may be configured to load the electronic component to be tested into the tray in an expansion state that expands such that a size of each of storage grooves of the tray expands greater than a size of the electronic component, and contract the tray to which the loading process is performed to switch the tray in the expansion state into the tray in a contraction state in which a size of each storage groove is reduced.

According to the present disclosure, the tray ma include storage grooves to store the electronic component; and a tray main body in which a plurality of storage grooves is formed. The tray main body may expand such that the size of each of the storage grooves expands greater than the size of the electronic component by heating, and be contracted such that the size of each of the storage grooves is reduced by cooling.

According to the present disclosure, a handling method of an electronic component may include performing a loading process of loading an electronic component on a tray; and performing a test process of testing the electronic component stored in the tray. The performing of the loading process includes: loading the electronic component to be tested on the tray in an expansion state in which a size of each of the storage grooves of the tray expands greater than a size of the electronic component; and switching the tray into an contraction state by contracting the tray on which the loading process is performed and reducing the size of each of the storage grooves.

According to the present disclosure, the following effects can be provided.

The present disclosure can be implemented to perform the loading process of loading each electronic component with respect to the tray in the expansion state and then switch the tray from the expansion state to the contraction state. Accordingly, the present disclosure may improve not only the easiness and safety of the loading process with respect to the electronic components corresponding to a microchip but also the precision of the test process of testing the electronic components stored in the tray.

### BRIEF DESCRIPTION OF THE DRAWINGS

FIG. 1 is a schematic block diagram of a test handler for an electronic component according to the present disclosure.

FIG. 2 is a schematic plan view showing a tray according to the present disclosure switched between a contraction state and an expansion state.

FIG. 3 is a schematic enlarged view showing an electronic component stored in a storage groove by enlarging part A in FIG. 2.

FIG. 4 is a schematic enlarged view showing an electronic component stored in a storage groove by enlarging part B in FIG. 2.

FIG. 5 is a schematic planar composition diagram of the test handler for an electronic component according to the present disclosure.

FIGS. 6 and 7 are schematic flowcharts showing a handling method of an electronic component according to the present disclosure.

### DETAILED DESCRIPTION OF THE DISCLOSURE

Hereinbelow, an embodiment of a test handler for an electronic component according to the present disclosure will be described in detail with reference to accompanying drawings.

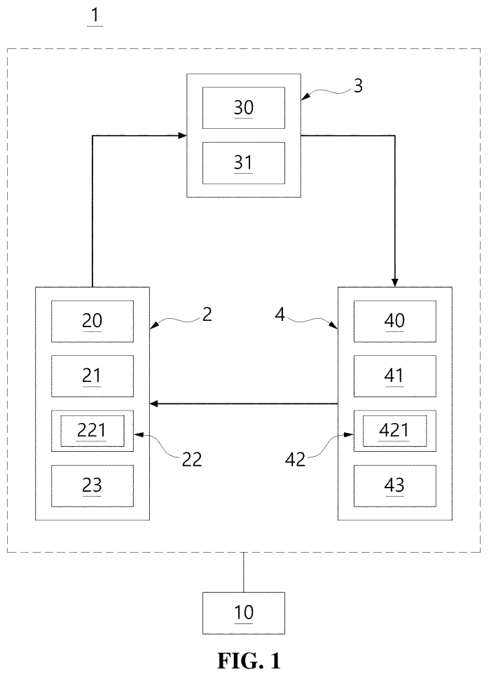

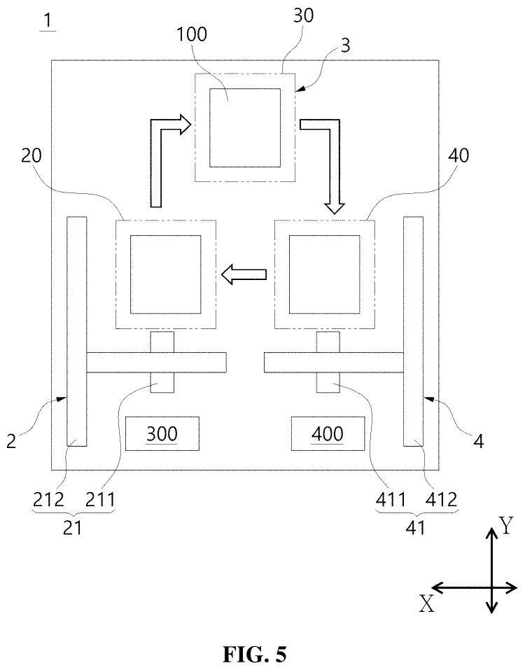

Referring to FIGS. 1 to 5, according to the present disclosure, the test handler 1 for an electronic component may perform a loading process in which an electronic component 200 to be tested is loaded on a tray 100, and a test process in which the electronic component 200 loaded on the tray 100 is tested. The electronic component 200 may be a memory a memory semiconductor device, a non-memory semiconductor device, a central processing unit (CPU), and the like. The electronic component 200 may be a high bandwidth memory (HBM), a double data rate (DDR), a graphics double data rate (GDDR), a low power double data rate (LPDDR), and the like. According to the present disclosure, the test handler 1 for an electronic component may be implemented to be suitable for handling the electronic component 200 that corresponds to a microchip formed to have a micro size such as a HBM, a DDR, a GDDR, a LPDDR, and the like. To this end, according to the present disclosure, the test handler 1 for an electronic component may use the tray 100. Prior to describing the embodiment of the test handler 1 for an electronic component according to the present disclosure, the tray 100 will be described as follows.

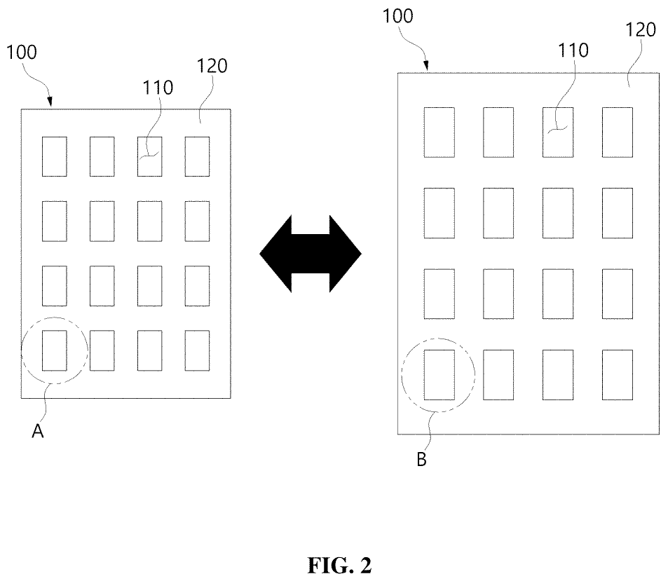

Referring to FIGS. 2 to 4, the tray 100 may store the electronic component 200 therein. The tray 100 may be implemented into a tray according to the present disclosure. The tray 100 may include storage grooves 110 and a tray main body 120.

The storage grooves 110 may store each electronic component 200. The storage grooves 110 may be formed to have a form corresponding to the electronic component 200. Each storage groove 110 may be implemented into a groove formed with a certain depth on a surface of the tray main body 120.

The tray main body 120 may constitute the overall appearance of the tray 100. The tray main body 120 may include a plurality of storage grooves 110. The plurality of storage grooves 110 may be formed on the tray main body 120 to be disposed at positions spaced apart from each other.

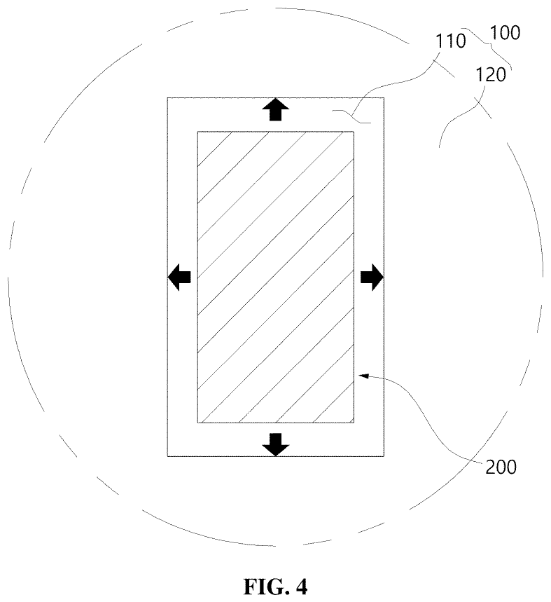

As shown in FIG. 2, the tray main body 120 may expand by heating. As the tray main body 120 expands, the size of each storage groove 110 may expand as shown in FIG. 4. Accordingly, the tray 100 may be switched into an expansion state, as shown in the right view of FIG. 2. When the tray 100 is switched into the expansion state, as shown in FIG. 4, the size of each storage groove 110 may expand greater than the size of each electronic component 200. Accordingly, the tray 100 may serve to improve the easiness and stability of the loading process of storing electronic components 200 corresponding to microchips into the storage grooves 110 by using expansion caused by heating. In the storing process in which the electronic components 200 are stored in the storage grooves 110, the expansion may reduce the probability that the electronic components 200 will touch or collide with the tray main body 120. At this point, the size of each storage groove 110 may relate to the area of each storage groove 110 when the storage grooves 110 are shown from the vertically upper side with the tray main body 120 laying horizontally. The size of each storage groove 110 may relate to both the area of each storage groove 110 and the depth of each storage groove 110.

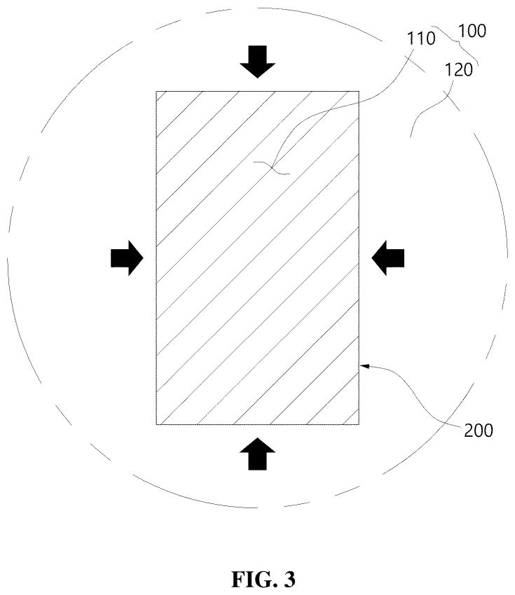

The tray main body 120 may be contracted by cooling. As the tray main body 120 is contracted, the size of each storage groove 110 may be reduced, as shown in FIG. 3. Accordingly, the tray 100 may be switched into a contraction state, as shown in the left view of FIG. 2. As the tray 100 is switched into the contraction state by using the contraction caused by cooling, the electronic components 200 corresponding to microchips may be disposed at a location where the test process is performed. In this case, when the tray main body 120 is contracted by the cooling, as shown in FIG. 3, the tray main body 120 may be brought into contact with side surfaces of the electronic components 200 stored in the storage grooves 110 to align the electronic components 200. Therefore, the tray 100 may serve to improve the precision of the test process by improving the precision of work of aligning the electronic components 200. In this case, the tray main body 120 may match the location, posture, interval, etc., of each electronic component 200 to a location, a posture, an interval, etc. of each electronic component 200 to be aligned when the test process is performed. Furthermore, since the tray main body 120 is brought into contact with the side surfaces of the electronic components 200 stored in the storage grooves 110, the tray 100 may firmly support the electronic components 200 stored in the storage grooves 110 without adsorbing the electronic components 200 by using an absorptive power. Therefore, the tray 100 may remove an absorption device (not shown), etc., thereby serving to reduce installation cost and operation cost.

The tray main body 120 may be made of stainless steel. Accordingly, the tray main body 120 may have enough durability to withstand repeated heating and cooling. Furthermore, the tray main body 120 is implemented to have a lower thermal expansivity than aluminum (Al), improving the easiness and stability of work of controlling the amount of expansion caused by heating and the amount of contraction caused by cooling. For example, the tray main body 120 may be made of steel use stainless (SUS) and steel type stainless (STS).

The tray main body 120 may be made of silicon. Accordingly, the tray main body 120 is implemented to have a thermal expansivity lower than stainless steel, further improving the easiness and stability of work of controlling the amount of expansion caused by heating and the amount of contraction caused by cooling. Furthermore, since the tray main body 120 is made of silicon, the tray main body 120 may be implemented such that the test process is performed in an environment similar to an environment where a probe tester tests a silicon wafer. Therefore, the tray main body 120 may serve to improve the precision of the test process. Meanwhile, the tray main body 120 may be made of different types of materials such as glass, and the like.

The tray main body 120 may have a polygonal form having N (where N is a natural number greater than 2) side surfaces. For example, the tray main body 120 may have a rectangular plate form. The tray main body 120 may have a circular form having a curved side surface. For example, the tray main body 120 may have a circular plate form. The tray main body 120 may have an aspherical form having an aspheric side surface. For example, the tray main body 120 may have an oval plate form.

To perform the loading process and the test process by using the tray 100 having the above-described forms, the test handler 1 for an electronic component according to the present disclosure may include a loading unit 2 and a test unit 3.

Referring to FIGS. 1 to 5, the loading unit 2 may perform the loading process. The loading unit 2 may perform the loading process by loading each electronic component 200 to be tested to the tray 100. In this case, the loading unit 2 may store the electronic component 200 to be tested in the storage grooves 110 included in the tray 100. The loading unit 2 may perform the loading process to the tray 100 laying horizontally. The loading unit 2 may be coupled to a main body. The main body may be set up in workplace.

The loading unit 2 may load the electronic component 200 to be tested on the tray 100 in the expansion state. When the tray 100 is in the expansion state, the size of each storage groove 110 may expand greater than the size of the electronic component 200. Therefore, the loading unit 2 may easily and stably store the electronic components 200 corresponding to microchips in the storage grooves 110. After the loading process is performed, the loading unit 2 may contract the tray 100 to change into the tray 100 in the contraction state. When the tray 100 is switched into the contraction state by the contraction, the size of each storage groove 110 may be reduced. Accordingly, the loading unit 2 may arrange the electronic components 200 loaded on the tray 100 to locations where the test process is performed.

Likewise, since the loading unit 2 performs the loading process to the tray 100 in the expansion state and then switches the tray 100 into the contraction state, according to the present disclosure, the test handler 1 for an electronic component can improve the ease and the stability of the loading process even to the electronic components 200 corresponding to microchips, and also improve the precision of the test process.

Referring to FIGS. 1 to 5, the loading unit 2 may include a loading picker 21.

The loading picker 21 may load the electronic component 200 to be tested on the tray 100 in the expansion state. The loading picker 21 may pick up the electronic component 200 to be tested from a first storage unit 300 to store the electronic component 200 in each storage groove 110 of the tray 100 in the expansion state located in a loading location 20. The first storage unit 300 may store one of a wafer ring, a reel, or a user tray. Accordingly, the loading picker 21 may pick up the electronic component to be tested from one of a wafer ring, a reel, or a user tray. The first storage unit 300 may be installed at the main body. The first storage unit 300 may be installed outside the main body. The loading location 20 may be a location where the tray 100 is located where the loading process is performed. A loading stage (not shown) supporting the tray 100 may be installed at the loading location 20. The loading stage may be formed into a size enough to support the tray 100 in the expansion state. Accordingly, the loading stage may be implemented to also support the tray 100 in the contraction state. The loading picker 21 may pick up the plurality of electronic components at the same time.

The loading picker 21 may be moved along a first axial direction (X-axial direction) and a second axial direction (Y-axial direction). The first axial direction (X-axial direction) and the second axial direction (Y-axial direction) may be perpendicular to each other. The loading picker 21 may be raised and lowered in an upward-downward direction. The upward-downward direction may be perpendicular to both the first axial direction (X-axial direction) and the second axial direction (Y-axial direction). The loading picker 21 may perform the loading process while moving along the first axial direction (X-axial direction), the second axial direction (Y-axial direction), and the upward-downward direction.

The loading picker 21 may include a loading pick-up unit 211 and a loading gantry 212.

The loading pick-up unit 211 may absorb the electronic component 200 to be tested. The loading pick-up unit 211 may absorb and pick up the electronic component 200 from the first storage unit 300, and may store the picked-up electronic component 200 in each storage groove 110 of the tray 100 located at the loading location 20. When the electronic component 200 is stored in each storage groove 110 of the tray 100 located at the loading location 20, the loading pick-up unit 211 may stop absorption with respect to the electronic component 200 or spray gas. The loading pick-up unit 211 may absorb the plurality of electronic components 200 at the same time.

The loading gantry 212 may move the loading pick-up unit 211. The loading gantry 212 may move the loading pick-up unit 211 in the first axial direction (X-axial direction), the second axial direction (Y-axial direction), and the upward-downward direction. Accordingly, the loading pick-up unit 211 may perform the loading process while moving between the first storage unit 300 and the loading location 20.

Referring to FIGS. 1 to 5, the loading unit 2 may include a loading adjustment device 22.

The loading adjustment device 22 may adjust the temperature of the tray 100. The loading adjustment device 22 may heat the tray 100 and switch the tray 100 into the expansion state. When the tray 100 in the expansion state is located at the loading location 20, the loading adjustment device 22 may heat the tray 100 so that the tray 100 is maintained in the expansion state during performing the loading process. The loading adjustment device 22 may adjust the temperature of the tray 100 located at the loading location 20. The loading adjustment device 22 may be installed at the loading stage.

The loading adjustment device 22 may cool the tray 100 in the expansion state and switch the tray 100 in the expansion state into the tray 100 in the contraction state. In this case, after the loading process is performed, the loading adjustment device 22 may cool the tray 100 to which the electronic components 200 to be tested are loaded and switch the tray 100 into the tray 100 in the contraction state. The loading adjustment device 22 may reduce the size of each storage groove 110 into the size of the electronic component 200 by cooling the tray 100, and align the electronic components 200. In this case, the loading adjustment device 22 may contract the tray 100, such that the tray main body 120 is brought into contact with the side surfaces of the electronic components 200 stored in the storage grooves 110 by cooling the tray 100 and align the electronic components 200. Therefore, according to the present disclosure, the test handler 1 for an electronic component may serve to improve the precision of the test process by improving the precision of the work of aligning the electronic components 200 to which the loading process is performed. In this case, by cooling the tray 100, the loading adjustment device 22 may match the location, posture, interval, etc., of each electronic component 200 to a location, a posture, an interval, etc. of each electronic component 200 to be aligned when the test process is performed. Furthermore, since the tray main body 120 is brought into contact with the side surfaces of the electronic components 200 stored in the storage grooves 110, according to the present disclosure, the test handler 1 for an electronic component may firmly support the electronic components 200 loaded on the tray 100 even without absorbing the electronic components 200 stored in the storage grooves 110 by using the absorption force. Therefore, according to the present disclosure, the test handler 1 for an electronic component may not include an absorption device, etc., to absorb the electronic components 200 loaded on the tray 100, so that the installation cost and operation cost of the test handler.

The loading adjustment device 22 may switch the tray 100 between the expansion state and the contraction state. The loading adjustment device 22 may switch the tray 100 into the expansion state by heating the tray 100. When the tray 100 is located at the loading location 20 in the expansion state, the loading adjustment device 22 may switch the tray 100 into the expansion state by heating the tray 100 so that the tray 100 is maintained in the expansion state. The loading adjustment device 22 may switch the tray 100 into the contraction state by cooling the tray 100. The loading adjustment device 22 may include a Peltier element 221 to heat and cool the tray 100. The loading adjustment device 22 may change a direction of current applied to the Peltier element 221 to switch heating and cooling with respect to the tray 100 by using the Peltier element 221. The Peltier element 221 may be installed at the loading stage. The Peltier element 221 may be disposed at a position where it may be brought into contact with the tray 100 supported by the loading stage. Although not shown in the drawing, the loading adjustment device 22 may include a loading heater to heat the tray 100, and a loading cooler to cool the tray 100. The loading adjustment device 22 may include a loading circulating device to circulate a temperature adjustment fluid to adjust the temperature of the tray 100. In this case, the loading adjustment device 22 may adjust the temperature of the temperature adjustment fluid to perform heating and cooling with respect to the tray 100. The loading adjustment device 22 may perform natural cooling to the tray 100. The loading adjustment device 22 may include a film heater. In this case, the loading adjustment device 22 may use the film heater to heat the tray 100 so that the tray 100 expands, and perform natural cooling so that the tray 100 is contracted. As described above, the loading adjustment device 22 may heat the tray 100 by using at least one of the Peltier element 221, the loading heater, the loading circulating device, and the film heater. The loading adjustment device 22 may cool the tray 100 by using at least one of the Peltier element 221, the loading cooler, the loading circulating device, and natural cooling.

Referring to FIGS. 1 to 5, the loading unit 2 may include a loading measurement device 23.

The loading measurement device 23 may measure the size of the tray 100. The loading measurement device 23 may measure the size of the tray 100 and then provide the measured value to the loading adjustment device 22. The loading measurement device 23 may provide the measured value to the loading adjustment device 22 by wired or wireless communication, etc. The loading measurement device 23 may capture the tray 100 located at the loading location 20 to acquire a captured image, and compare the acquired image to a pre-stored reference image to measure the size of the tray 100. In this case, the loading measurement device 23 may include a camera. The reference image may be stored in the loading measurement device 23 in advance after drawn through a pre-test, and the like. The loading measurement device 23 may entirely scan the tray 100 located at the loading location 20 to measure the size of the tray 100. In this case, the loading measurement device 23 may include a scanner. The loading measurement device 23 may use an optical sensor, a laser sensor, and the like to measure the size of the tray 100.

By using the size of the tray 100 measured by the loading measurement device 23, the loading adjustment device 22 may cool the tray 100 until the size of each storage groove 110 matches with the size of the electronic component 200. In this case, when the size of the tray 100 measured by the loading measurement device 23 becomes equal to the preset contraction size of the tray, the loading adjustment device 22 may stop cooling with respect to the tray 100. Accordingly, according to the present disclosure, the test handler 1 for an electronic component may switch the tray 100 into the contraction state to improve the precision of work of aligning the electronic component 200. The contraction size is a size value of the tray 100 when the size of each storage groove 110 is equal to the size of the electronic component 200, and the contraction size may be derived through a pretest, etc., and preset in the loading measurement device 23 in advance.

The loading measurement device 23 may be arranged at a position spaced upward from the tray 100. In this case, the loading measurement device 23 may be disposed above the tray 100 that is located at the loading location 20. The loading measurement device 23 may measure an area of the tray 100 while being located above the tray 100. In this case, the loading measurement device 23 may measure the area of the tray 100 when the tray 100 laying horizontally is viewed from the vertically upper side. The loading adjustment device 22 may cool the tray 100 by using the area of the tray 100 measured by the loading measurement device 23 until the area of each storage groove 110 becomes equal to the area of the electronic component 200. In this case, when the area of the tray 100 measured by the loading measurement device 23 becomes equal to the preset contraction area of the tray, the loading adjustment device 22 may stop cooling with respect to the tray 100. Accordingly, according to the present disclosure, the test handler 1 for an electronic component may switch the tray 100 into the contraction state to improve the precision of work of aligning the electronic component 200. The contraction area is an area value of the tray 100 when the area of each storage groove 110 is equal to the area of the electronic component 200, and the contraction area may be derived through a pretest, etc., and preset in the loading measurement device 23 in advance. Meanwhile, the area of each storage groove 110 is based on when each storage groove 110 is viewed from the vertically upper side with the tray 100 laying horizontally. The area of the electronic component 200 is based on when the electronic component 200 is viewed from the vertically upper side with the electronic component 200 laying horizontally.

Referring to FIGS. 1 to 5, the test unit 3 may perform the test process where the electronic component stored in the tray 100 is tested. The test unit 3 may perform the test process with respect to the tray 100 located at the test location 30. The test location 30 may be arranged at a position spaced apart from the loading location 20. The test unit 3 may be installed at the main body.

The test unit 3 may perform the test process with respect to the tray 100 that is switched into the contraction state by the loading unit 2. In this case, when the loading unit 2 performs the loading process with respect to the tray 100 in the expansion state and then cools the tray 100 in the expansion state to switch the tray 100 into the contraction state, the transfer unit 10 may transfer the tray 100 in the contraction state from the loading unit 2 to the test unit 3. Accordingly, the test unit 3 may perform the test process with respect to the tray 100 that is switched into the contraction state by the loading unit 2. The transfer unit 10 may transfer the tray 100 by pushing and pulling the tray 100. The transfer unit 10 may transfer the tray 100 switched into the contraction state after the loading process, from the loading location 20 to the test location 30. The transfer unit 10 may be installed at the main body.

The test unit 3 may include a probe card 31. When the tray 100 is located at the test location 30, the probe card 31 may perform the test process by being connected to the electronic components 200 stored in the tray 100. The probe card 31 may include a plurality of probes (not shown) provided to be connected to the electronic components 200. The probe card 31 may be connected to the electronic components stored in the tray 100 in the contraction state.

Referring to FIGS. 1 to 5, according to the present disclosure, the test handler 1 for an electronic component may include an unloading unit 4.

The unloading unit 4 may perform an unloading process unloading the tested electronic component 200 from the tray 100. When the test unit 3 performs the test process and then the tray 100 is transferred to the unloading unit 4 by the transfer unit 10, the unloading unit 4 may perform the unloading process with respect to the tray 100. In this case, the unloading unit 4 may respectively pick up the tested electronic components 200 to the storage grooves 110 included in the tray 100. The unloading unit 4 may perform the unloading process to the tray 100 laying horizontally. The unloading unit 4 may be coupled to the main body.

The unloading unit 4 may switch the tray 100 in the contraction state, which is transferred from the test unit 3, into the tray 100 in the expansion state and then unload the tested electronic components 200 from the tray 100 in the expansion state. When the tray 100 is in the expansion state, the size of each storage groove 110 may expand greater than the size of the electronic component 200. Therefore, the unloading unit 4 may easily and stably unload the electronic components 200 corresponding to microchips in the storage grooves 110. In this case, the unloading unit 4 may use a vision unit (not shown) to check locations of the electronic components 200 stored in the storage grooves 110 and unload the electronic components 200.

After the unloading unit 4 performs the unloading process with respect to the tray 100 in the expansion state, the loading unit 2 may perform the loading process with respect to the tray 100 in the expansion state transferred from the unloading unit 4. Accordingly, according to the present disclosure, with respect to the tray 100 that passes the unloading unit 4, the loading unit 2 may perform the loading process by directly using the tray 100 switched into the expansion state by the unloading unit 4, so the test handler 1 for an electronic component can reduce the overall process time. The tray 100 in the expansion state may be transferred from the unloading unit 4 to the loading unit 2 by the transfer unit 10.

Referring to FIGS. 1 to 5, the unloading unit 4 may include the unloading picker 41.

The unloading picker 41 may unload the tested electronic component 200 from the tray 100 in the expansion state. The unloading picker 41 may pick up the tested electronic components 200 from the tray 100 in the expansion state located at an unloading location 40 and place the electronic components 200 on a second storage unit 400. In this case, the unloading picker 41 may grade the electronic components 200 according to a tested result obtained from the test process and place the electronic components 200. The second storage unit 400 may store one of a wafer ring, a reel, or a user tray. Accordingly, the unloading picker 41 may place the tested electronic components on one of a wafer ring, a reel, or a user tray. The second storage unit 400 may be installed at the main body. The second storage unit 400 may be installed outside the main body. The unloading location 40 may be a location where the tray 100 is located when the unloading process is performed. An unloading stage (not shown) supporting the tray 100 may be installed at the unloading location 40. The unloading stage may be formed into a size enough to support the tray 100 in the expansion state. Accordingly, the unloading stage may be implemented to also support the tray 100 in the contraction state. The unloading picker 41 may pick up the plurality of electronic components at the same time.

Meanwhile, the second storage unit 400 and the first storage unit 300 may store the same type of storage means. For example, according to the present disclosure, the test handler 1 for an electronic component may pick up the electronic components 200 to be tested from the wafer ring, and may place the tested electronic components 200 on the wafer ring. The second storage unit 400 and the first storage unit 300 may store different types of storage means. For example, according to the present disclosure, the test handler 1 for an electronic component may pick up the electronic components 200 to be tested from the wafer ring, and may place the tested electronic components 200 on the reel.

The unloading picker 41 may be moved along the first axial direction (X-axial direction) and the second axial direction (Y-axial direction). The unloading picker 41 may be raised and lowered in the upward-downward direction. The unloading picker 41 may perform the unloading process while moving along the first axial direction (X-axial direction), the second axial direction (Y-axial direction), and the upward-downward direction.

The unloading picker 41 may include an unloading pick-up unit 411 and an unloading gantry 412.

The unloading pick-up unit 411 may absorb each tested electronic component 200. The unloading pick-up unit 411 may absorb and pick up each tested electronic component 200 from each storage groove 110 of the tray 100 located at the unloading location 40, and may place each picked-up electronic component 200 on the second storage unit 400. When each electronic component 200 is placed in the second storage unit 400, the unloading pick-up unit 411 may stop the absorbing to each electronic component 200 or spray gas. The unloading pick-up unit 411 may absorb the plurality of electronic components 200 at the same time.

The unloading gantry 412 may move the unloading pick-up unit 411. The unloading gantry 412 may move the unloading pick-up unit 411 in the first axial direction (X-axial direction), the second axial direction (Y-axial direction), and the upward-downward direction. Accordingly, the unloading pick-up unit 411 may be moved between the unloading location 40 and the second storage unit 400 and perform the unloading process.

Referring to FIGS. 1 to 5, the unloading unit 4 may include an unloading adjustment device 42.

The unloading adjustment device 42 may adjust the temperature of the tray 100. The unloading adjustment device 42 may heat the tray 100 in the contraction state to switch the tray 100 into the expansion state. The unloading adjustment device 42 may adjust the temperature of the tray 100 located at the unloading location 40. The unloading adjustment device 42 may be installed at the unloading stage.

Meanwhile, when the loading unit 2 performs the loading process by directly using the tray 100 switched into the expansion state by the unloading unit 4, the loading adjustment device 22 included in the loading unit 2 may cool the tray 100 to only perform the work of switching the tray 100 in the expansion state into the tray 100 in the contraction state, the unloading adjustment device 42 included in the unloading unit 4 may heat the tray 100 to only perform the work of switching the tray 100 in the contraction state into the tray 100 in the expansion state.

The unloading adjustment device 42 may include a Peltier element 421 to heat the tray 100. The Peltier element 421 may be installed at the unloading stage. The Peltier element 421 may be disposed at a position where it may be brought into contact with the tray 100 supported by the unloading stage. Although not shown in the drawing, the unloading adjustment device 42 may include an unloading heater to heat the tray 100. The unloading adjustment device 42 may include an unloading circulating device to circulate a temperature adjustment fluid to adjust the temperature of the tray 100. In this case, the unloading adjustment device 42 may adjust the temperature of the temperature adjustment fluid to perform heating with respect to the tray 100. The unloading adjustment device 42 may include a film heater. In this case, the unloading adjustment device 42 may use the film heater to heat and expand the tray 100. As described above, the unloading adjustment device 42 may heat the tray 100 by using at least one of the Peltier element 421, the unloading heater, the unloading circulating device, or the film heater.

The unloading adjustment device 42 may cool the tray 100 so that the tray 100 transferred from the test unit 3 is maintained in the contraction state until the unloading process is performed with respect to the tray 100 located at the unloading location 40. In this case, the unloading adjustment device 42 may cool the tray 100 by using at least one of the Peltier element 421, the unloading cooler that cools the tray 100, and the unloading circulating device that circulates the temperature adjustment fluid at a temperature at which the tray 100 is cooled. The unloading adjustment device 42 may perform natural cooling to the tray 100. As described above, the unloading adjustment device 42 may cool the tray 100 by using at least one of the Peltier element 421, the unloading cooler, the unloading circulating device, and the natural cooling.

Referring to FIGS. 1 to 5, the unloading unit 4 may include an unloading measurement device 43.

The unloading measurement device 43 may measure the size of the tray 100. The unloading measurement device 43 may measure the size of the tray 100 and then provide the measured value to the unloading adjustment device 42. The unloading measurement device 43 may provide the measured value to the unloading adjustment device 42 by wired or wireless communication, etc. The unloading measurement device 43 may capture the tray 100 located at the unloading location 40 to acquire a captured image, and compare the acquired image to a pre-stored reference image to measure the size of the tray 100. In this case, the unloading measurement device 43 may include a camera. The reference image may be stored in the unloading measurement device 43 in advance after drawn through a pre-test, and the like. The unloading measurement device 43 may entirely scan the tray 100 located at the unloading location 40 to measure the size of the tray 100. In this case, the unloading measurement device 43 may include a scanner. The unloading measurement device 43 may use an optical sensor, a laser sensor, and the like to measure the size of the tray 100.

By using the size of the tray 100 measured by the unloading measurement device 43, the unloading adjustment device 42 may heat the tray 100 until the size of each storage groove 110 expands to a preset target size. The target size may be a size of each storage groove 110 enough to secure the easiness and stability of the unloading process, and be derived through a pretest, etc., and be preset in the unloading measurement device 43 in advance. In this case, when the size of the tray 100 measured by the unloading measurement device 43 becomes equal to the preset expansion size of the tray, the unloading adjustment device 42 may stop heating with respect to the tray 100. Accordingly, according to the present disclosure, the test handler 1 for an electronic component can improve the precision of the work of securing the easiness and stability of the unloading process by switching the tray 100 into the expansion state. The expansion size is a size value of the tray 100 when the size of each storage groove 110 is equal to the target size, and the expansion size may be derived through a pretest, etc., and be preset in the unloading measurement device 43 in advance.

The unloading measurement device 43 may be arranged at a position spaced upward from the tray 100. In this case, the unloading measurement device 43 may be disposed above the tray 100 that is located at the unloading location 40. The unloading measurement device 43 may measure an area of the tray 100 while being located above the tray 100. In this case, the unloading measurement device 43 may measure the area of the tray 100 when the tray 100 laying horizontally is viewed from the vertically upper side. The unloading adjustment device 42 may heat the tray 100 by using the area of the tray 100 measured by the unloading measurement device 43 until the area of each storage groove 110 expands to the preset target area. In this case, when the area of the tray 100 measured by the unloading measurement device 43 becomes equal to the preset expansion area of the tray, the unloading adjustment device 42 may stop heating with respect to the tray 100. Accordingly, according to the present disclosure, the test handler 1 for an electronic component can improve the precision of the work of securing the easiness and stability of the unloading process by switching the tray 100 into the expansion state. The target area may be an area of each storage groove 110 enough to secure the easiness and stability of the unloading process, and be derived through a pretest, etc., and be preset in the unloading measurement device 43 in advance. The expansion area is an area value of the tray 100 when the area of each storage groove 110 is equal to the target area, and the expansion area may be derived through a pretest, etc., and preset in the unloading measurement device 43 in advance. Meanwhile, the area of each storage groove 110 is based on when each storage groove 110 is viewed from the vertically upper side with the tray 100 laying horizontally.

As described above, according to the present disclosure, the test handler 1 for an electronic component may repeatedly perform the process of performing the unloading process with respect to the tray 100 in the expansion state at the unloading location 40 and then transferring the tray 100 in the expansion state from the unloading location 40 to the loading location 20; performing the loading process with respect to the tray 100 in the expansion state at the loading location 20 and then switching the tray 100 in the expansion state into the tray 100 in the contraction state; transferring the tray 100 in the contraction state from the loading location 20 to the test location 30 and performing the test process and then transferring the tray 100 in the contraction state from the test location 30 to the unloading location 40; and switching the tray 100 in the contraction state into the tray 100 in the expansion state at the unloading location 40 and then performing the unloading process.

As described above, according to the present disclosure, an embodiment of a handling method of an electronic component will be described in detail with reference to accompanying drawings.

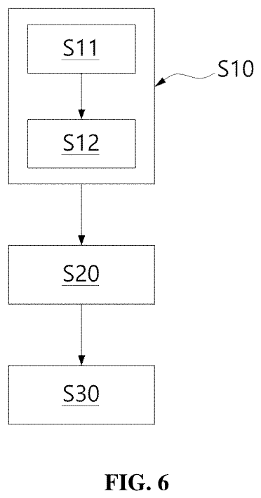

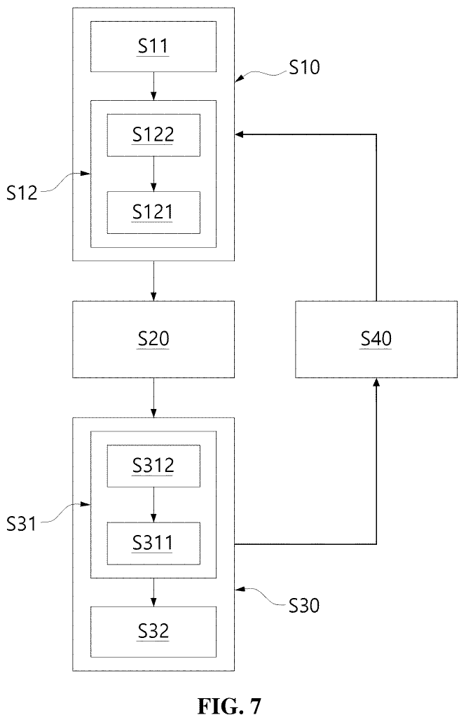

Referring to FIGS. 1 to 7, according to the present disclosure, the handling method of an electronic component may be configured to use the tray 100 to handle the electronic component 200. According to the present disclosure, the handling method of an electronic component may be performed by the test handler 1 for an electronic component according to the present disclosure. The electronic component 200 may be a memory a memory semiconductor device, a non-memory semiconductor device, a central processing unit (CPU), and the like. The electronic component 200 may be HBM, DDR, GDDR, LPDDR, and the like. According to the present disclosure, the handling method of an electronic component may be implemented to be suitable for handling the electronic component 200 that corresponds to a microchip formed to have a microscopic scale such as a HBM, a DDR, a GDDR, a LPDDR, and the like. To this end, according to the present disclosure, the handling method of an electronic component may include the following steps.

First, the loading process is performed, S10. The performing S10 of the loading process may be performed by loading each electronic component 200 on the tray 100. The performing S10 of the loading process may be performed by the loading unit 2.

Next, the test process is performed, S20. The performing S20 of the test process may be performed by testing each electronic component 200 stored in the tray 100. The performing S20 of the test process may be performed by the test unit 3. The performing S20 of the test process may be performed after performing S10 of the loading process.

At this point, the performing S10 of the loading process may include loading S11 each electronic component to be tested on the tray in the expansion state, and switching S12 the tray into the contraction state.

The loading S11 of each electronic component to be tested on the tray in the extension state may be performed by loading each electronic component 200 to be tested on the tray 100 in the extension state where a size of each storage groove 110 included in the tray 100 expands greater than a size of each electronic component 200. The loading S11 may be performed by the loading unit 2. Through the loading S11 of each electronic component on the tray in the expansion state, the electronic component 200 to be tested is loaded when the size of each storage groove 110 included in the tray 100 expands greater than the size of each electronic component 200. Therefore, according to the present disclosure, the handling method of an electronic component may easily and stability store the electronic components 200 corresponding to microchips into the storage grooves 110.

The switching S12 of the tray into the contraction state may be performed by contracting the tray 100 where the loading process is performed and switching the tray 100 in the contraction state where the size of each storage groove 110 is reduced. The switching S12 may be performed by the loading unit 2. The switching S12 of the tray into the contraction state may be performed as the loading adjustment device 22 cools the tray 100 to which the loading process is performed. Through the switching S12 of the tray into the contraction state, since the size of each storage groove 110 is reduced according to the switching of the tray 100 into the contraction state, according to the present disclosure, the handling method of an electronic component may arrange the electronic components 200 loaded on the tray 100 at the location where the test process will be performed. Accordingly, the handling method of an electronic component according to the present disclosure may improve the precision of the test process.

The switching S12 the tray into the contraction state may include cooling S121 the tray.

The cooling S121 the tray may be performed by cooling the tray 100. The cooling S121 of the tray may reduce the size of each storage groove 110 into the size of the electronic component 200 by cooling the tray 100, and align the electronic components 200. In this case, the tray main body 120 may be brought into contact with the side surfaces of the electronic components 200 stored in the storage grooves 110 to align the electronic components 200, and the handling method of an electronic component according to the present disclosure can improve the precision of the work of aligning the electronic components 200 to which the loading process is performed, thereby serving to improve the precision of the test process. Furthermore, since the tray main body 120 is brought into contact with the side surfaces of the electronic components 200 stored in the storage grooves 110, the handling method of an electronic component according to the present disclosure may allow the electronic components 200 stored in the storage grooves 110 to be firmly supported by the tray 100 without being absorbed by an absorption power. Therefore, according to the present disclosure, an absorption device, etc., to absorb the electronic components 200 loaded on the tray 100 may be omitted from the handling method of an electronic component, which can serve to reduce the installation and operation costs. The cooling S121 the tray may be performed by the loading unit 2. The cooling S121 the tray may be performed as the loading adjustment device 22 cools the tray 100 to which the loading process is performed.

The switching S12 the tray into the contraction state may include measuring S122 the size of the tray.

The measuring S122 the size of the tray may be performed as the loading unit 2 measures the size of the tray 100. The measuring S122 may be performed as the loading measurement device 23 measures the size of the tray 100 located at the loading location 20. The measuring S122 the size of the tray may be performed before the cooling S121 the tray. The measuring S122 of the size of the tray may be performed even when the cooling S121 the tray is performed. In this case, the measuring S122 the size of the tray may be performed periodically or intermittently when the cooling S121 the tray is performed. The measuring S122 of the size of the tray may be continuously performed when the cooling S121 the tray is performed. Accordingly, the cooling S121 the tray may be performed by cooling the tray 100 until the size of each storage groove 110 becomes equal to the size of each electronic component 200 by using the size of the tray 100 measured by the measuring S122 of the size of the tray. In this case, when the size of the tray 100 measured by the measuring S122 the size of the tray is equal to the contraction size, the cooling S121 the tray may stop the cooling with respect to the tray 100. Accordingly, according to the present disclosure, the handling method of an electronic component may switch the tray 100 into the contraction state to improve the precision of work of aligning the electronic component 200.

Meanwhile, the measuring S122 the size of the tray may be performed by measuring the area of the tray 100. Accordingly, the cooling S121 the tray may be performed by cooling the tray 100 by using the area of the tray 100 measured by the measuring S122 the size of the tray until the area of each storage groove 110 becomes equal to the area of each electronic component 200. In this case, when the size of the tray 100 measured by the measuring S122 the size of the tray is equal to the contraction size, the cooling S121 the tray may stop the cooling with respect to the tray 100. Accordingly, according to the present disclosure, the handling method of an electronic component may switch the tray 100 into the contraction state to improve the precision of work of aligning the electronic component 200.

At this point, the test process may be performed, S20, by performing the test process with respect to the tray 100 that is switched into the contraction state through the performing S10 of the loading process. In this case, through the performing S10 of the loading process, the loading process is performed with respect to the tray 100 in the expansion state and then the tray 100 in the expansion state is cooled to be switched into the contraction state, so that the transfer unit 10 may transfer the tray 100 in the contraction state from the loading unit 2 to the test unit 3. In this case, the transfer unit 10 may transfer the tray 100 in the contraction state from the loading location 20 to the test location 30. The performing S20 of the test process may be performed as the probe card 31 is connected to the electronic components 200 stored in the tray 100 and performs the test process.

Referring to FIGS. 1 to 7, the handling method of an electronic component according to the present disclosure may include performing S30 the unloading process.

The performing S30 of the unloading process may be performed by unloading the electronic components 200 from the tray 100. The performing S30 of the unloading process may be performed by the unloading unit 4. The performing S30 of the unloading process may be performed after the performing S20 of the test process. In this case, in the performing S30 of the unloading process, the unloading process may be performed with respect to the tray 100 transferred from the test location 30 to the unloading location 40 after the test process is performed.

The performing S30 of the unloading process may include switching S31 the tray into the expansion state, and unloading S32 each tested electronic component from the tray in the expansion state.

The switching S31 of the tray into the expansion state may be performed by switching the tray 100 switched into the contraction state through the switching S12 of the tray into the contraction state into the tray 100 in the expansion state. The switching S31 of the tray into the expansion state may switch the tray 100 in the contraction state into the tray 100 in the expansion state, which may expand the size of each storage groove 110. The switching S31 of the tray in the expansion state may be performed by the unloading unit 4. The switching S31 of the tray into the expansion state may be performed as the unloading adjustment device 42 switches the tray 100 in the contraction state into the tray 100 in the expansion state.

The unloading S32 of each tested electronic component from the tray in the expansion state may be performed by unloading each electronic component 200 from the tray 100 switched into the expansion state through the switching S31 of the tray into the expansion state. The switching S31 of the tray into the expansion state allows the size of each storage groove 110 to expand, so the unloading S32 of each tested electronic component from the tray in the expansion state may easily and stably unload the electronic components 200 corresponding to microchips from the storage grooves 110. The unloading S32 of each tested electronic component from the tray in the expansion state may be performed after the switching S31 of the tray in the expansion state is performed. The unloading S32 of each tested electronic component from the tray in the expansion state may be performed by the unloading unit 4.

Meanwhile, after the unloading S32 of each tested electronic component from the tray in the expansion state, each electronic component to be tested on may be loaded on the tray in the expansion state, S11. The loading S11 of each electronic component to be tested on the tray in the expansion state may be performed by loading each electronic component 200 to be tested on the tray 100 switched into the expansion state through the switching S31 of the tray into the expansion state. Accordingly, in the handling method of an electronic component according to the present disclosure, the performing S11 of the loading process may be performed by directly using the tray 100 in the expansion state to which the unloading process is performed through the performing S30 of the unloading process. Therefore, the handling method of an electronic component according to the present disclosure can reduce the entire process time, increasing the productivity of the electronic components to which the test process and the unloading process are performed. In this case, the handling method of an electronic component according to the present disclosure may include transferring S40 the tray in the expansion state. The transferring S40 of the tray in the expansion state may be performed by, after the unloading process is performed to the tray 100 in the expansion state, transferring the tray 100 in the expansion state from the unloading location 40 to the loading location 20. The transferring S40 of the tray in the expansion state may be performed by the transfer unit 10.

At this point, the switching S31 of the tray into the expansion state may include heating S311 the tray.

The heating S311 of the tray may be performed by heating the tray 100. The heating S311 of the tray may be performed by heating the tray 100 to expand the size of each storage groove 110 greater than the size of each electronic component. Accordingly, in the unloading of the tested electronic components from the tray in the expansion state, the electronic components 200 may be easily and stably unloaded from the storage grooves 110. The heating S311 of the tray may be performed by the unloading unit 4. The heating S311 of the tray may be performed as the unloading adjustment device 42 heats the tray 100 to which the test process is performed. In this case, the tray 100 may be heated at the unloading location 40 in the contraction state.

The switching S31 of the tray into the expansion state may include measuring S312 the size of the tray.

The measuring S312 of the size of the tray may be performed as the unloading unit 4 measures the size of the tray 100. The measuring S312 may be performed as the unloading measurement device 43 measures the size of the tray 100 located at the unloading location 40. The measuring S312 of the size of the tray may be performed before the heating S311 of the tray is performed. The measuring S312 of the size of the tray may be performed even when the heating S311 of the tray is performed. In this case, the measuring S312 the size of the tray may be performed periodically or intermittently when the heating S311 the tray is performed. The measuring S312 of the size of the tray may be continuously performed when the heating S311 the tray is performed. Accordingly, the heating S311 of the tray may be performed by heating the tray 100 until the size of each storage groove 110 expands to the target size by using the size of the tray 100 measured by the measuring S312 of the tray. In this case, when the size of the tray 100 measured by the measuring 312 of the size of the tray is equal to the expansion size, the heating S311 of the tray may stop the heating with respect to the tray 100. Accordingly, according to the present disclosure, the handling method of an electronic component can improve the precision of the work of securing the easiness and stability of the unloading process by switching the tray 100 into the expansion state.

Meanwhile, the measuring S312 the size of the tray may be performed by measuring the area of the tray 100. Accordingly, the heating S311 of the tray may be performed by heating the tray 100 until the area of each storage groove 110 expands to the target area by using the area of the tray 100 measured by the measuring S312 of the tray. In this case, when the area of the tray 100 measured by the measuring 312 of the size of the tray is equal to the expansion area, the heating S311 of the tray may stop the heating with respect to the tray 100. Accordingly, according to the present disclosure, the handling method of an electronic component can improve the precision of the work of securing the easiness and stability of the unloading process by switching the tray 100 into the expansion state.

The above-described present disclosure is not limited to the embodiment and accompanying drawings, and those skilled in the art will appreciate that various modifications, additions, and substitutions are possible, without departing from the scope and spirit of the present disclosure.

1. A test handler for an electronic component, the test handler comprising:
a loading unit performing a loading process of loading an electronic component to be tested to a tray; and
a test unit performing a test process of testing the electronic component stored in the tray,
wherein the loading unit is configured to load the electronic component to be tested into the tray in an expansion state that expands such that a size of each of storage grooves of the tray expands greater than a size of the electronic component, and contract the tray to which the loading process is performed to switch the tray in the expansion state into the tray in a contraction state in which a size of each storage groove is reduced.

2. The test handler of claim 1, wherein the loading unit comprises:
a loading adjustment device adjusting temperature of the tray; and
a loading picker loading the electronic component to be tested into the tray in the expansion state.

3. The test handler of claim 1, wherein the loading unit comprises a loading adjustment device cooling the tray in the expansion state and switching the tray from the expansion state to the contraction state, and
the loading adjustment device reduces the size of each of the storage grooves into the size of the electronic component by cooling of the tray and aligns the electronic component.

4. The test handler of claim 1, wherein the loading unit comprises a loading adjustment device to switch the tray between the expansion state and the contraction state, and
the loading adjustment device heats the tray by using at least one of a Peltier element, a loading heater, a loading circulating device, and a film heater.

5. The test handler of claim 1, wherein the loading unit comprises a loading adjustment device to switch the tray between the expansion state and the contraction state, and
the loading adjustment device cools the tray by using at least one of a Peltier element, a loading cooler, a loading circulating device, and natural cooling.

6. The test handler of claim 1, wherein the loading unit comprises a loading picker that picks the electronic component to be tested and loads the electronic component into the tray in the expansion state, and
the loading picker picks up the electronic component to be tested from one of a wafer ring, a reel, or a user tray.

7. The test handler of claim 1, wherein the loading unit comprises a loading adjustment device and a loading measurement device, the loading adjustment device switching the tray from the expansion state to the contraction state, and the loading measurement device measuring a size of the tray, and
the loading adjustment device cools the tray until a size of each of the storage grooves becomes equal to a size of the electronic component by using a size of the tray measured by the loading measurement device.

8. The test handler of claim 1, wherein the test unit performs the test process with respect to the tray switched into the contraction state by the loading unit.

9. The test handler of claim 8, wherein the test unit comprises a probe card connected to electronic components stored in the tray in the contraction state.

10. The test handler of claim 1, further comprising:
an unloading unit performing an unloading process of unloading the tested electronic component from the tray,
wherein the unloading unit is configured to switch the tray in the contracted state that is transferred from the test unit into the tray in the expansion state and then to unload the tested electronic component from the tray in the expansion state.

11. The test handler of claim 10, wherein the unloading unit comprises:
an unloading adjustment device configured to heat the tray in the contraction state to switch the tray in the contraction state into the tray in the expansion state; and
an unloading picker configured to unload the tested electronic component from the tray in the expansion state.

12. The test handler of claim 1, further comprising:
an unloading unit performing an unloading process of unloading the tested electronic component from the tray,
wherein the unloading unit comprises an unloading adjustment device to switch the tray between the expansion state and the contraction state, and
the unloading adjustment device is configured to heat the tray by using at least one of a Peltier element, an unloading heater, an unloading circulating device, and a film heater.

13. The test handler of claim 1, further comprising:
an unloading unit performing an unloading process of unloading the tested electronic component from the tray,
wherein the unloading unit comprises an unloading adjustment device to switch the tray between the expansion state and the contraction state, and
the unloading adjustment device is configured to cool the tray by using at least one of a Peltier element, an unloading cooler, an unloading circulating device, and natural cooling.

14. The test handler of claim 10, wherein, after the unloading unit performs the unloading process to the tray in the expansion state, the loading unit performs the loading process with respect to the tray in the expansion state that is transferred from the unloading unit.

15. The test handler of claim 10, wherein the unloading unit comprises an unloading picker configured to pick up the tested electronic component from the tray in the expansion state, and
the unloading picker is configured to place the picked-up electronic component on one of a wafer ring, a reel, or a user tray.

16. The test handler of claim 10, wherein the unloading unit comprises an unloading adjustment device configured to switch the tray from the contraction state to the expansion state, and an unloading measurement device configured to measure a size of the tray, and
wherein the unloading adjustment device is configured to use the size of the tray measured by the unloading measurement device to heat the tray until the size of each of the storage grooves expands to a preset-target size.

17. A tray comprising:
a storage groove storing an electronic component therein; and
a tray main body comprising a plurality of storage grooves,
wherein the tray main body is expanded such that the size of each of the storage grooves expands greater than the size of the electronic component by heating, and is contracted such that the size of each of the storage grooves is reduced by cooling.

18. The tray of claim 17, wherein the tray main body is made of one of silicon, stainless steel, or glass.

19. The tray of claim 17, wherein, when the tray main body is contracted such that the size of each of the storage grooves is reduced by cooling, the tray main body is brought into contact with side surfaces of electronic components stored in the storage grooves to align the electronic components.

20. The tray of claim 17, wherein the tray main body has one of a polygonal form having N (N is a natural number greater than 2) side surfaces, a circular form having a curved side surface, or an aspherical form having an aspheric side surface.
